(19) United States
(12) Patent Application Publication
(10) Pub. No.: US 2026/0088252 A1
(43) Pub. Date: Mar. 26, 2026

(54) APPARATUS FOR TREATING SUBSTRATE AND METHOD FOR TREATING SUBSTRATE

(71) Applicant: SEMES CO., LTD., Cheonan-si (KR)

(72) Inventors: YOUNG KUK KIM, Cheonan-si (KR); SHANT ARAKELYAN, Cheonan-si (KR); JAE HONG MIN, Seoul (KR); TAE HOON JO, Seoul (KR); JA MYUNG GU, Cheonan-si (KR)

(73) Assignee: SEMES CO., LTD., Cheonan-si (KR)

(21) Appl. No.: 19/409,029

(22) Filed: Dec. 4, 2025

Related U.S. Application Data
(63) Continuation of application No. 17/518,480, filed on Nov. 3, 2021.

(30) Foreign Application Priority Data
Nov. 5, 2020 (KR) 10-2020-0147030

(51) Int. Cl. H01J 37/32

(52) U.S. Cl. CPC H01J 37/32174; H01J 37/32642

(57) ABSTRACT

A substrate treating apparatus includes a processing chamber having an inner processing space, a support unit supporting a substrate in the processing space, a gas supply unit supplying processing gas into the treatment space, and a RF power for supplying an RF signal to excite the processing gas into a plasma state. The support unit includes an edge ring surrounding the substrate, a coupling ring disposed under the edge ring and including an electrode therein, and a cable connected to the electrode. The end of the cable is grounded.

### CROSS-REFERENCE TO RELATED APPLICATIONS

This application is a continuation of U.S. application Ser. No. 17/518,480 filed on Nov. 3, 2021, which has a claim for priority under 35 U.S.C. § 119 is made to Korean Patent Application No. 10-2020-0147030 filed on Nov. 5, 2020, in the Korean Intellectual Property Office, the entire contents of each of which are hereby incorporated by reference.

### BACKGROUND

The exemplary embodiments of the inventive concept described herein relate to an apparatus for treating a substrate and a method for treating the substrate. More particularly, embodiments of the inventive concept disclosed herein relate to a substrate treating apparatus and method for controlling harmonics generated during a plasma treatment.

During a semiconductor device manufacturing process, a desired pattern is formed on a substrate by performing various processes such as photolithography, etching, ashing, ion implantation, thin film deposition, cleaning, etc. Among them, the etching process is a process of removing selectively at least a portion of a film formed on the substrate, and wet etching and dry etching are used. For the dry etching, an etching device using a plasma is used.

Generally, in order to generate the plasma, an electromagnetic field is formed in an inner space of a processing chamber, and the electromagnetic field excites a processing gas provided in the processing chamber into a plasma state. The plasma refers to an ionized gas state comprising ions, electrons, radicals, or the like. The plasma is generated by a very high temperature, a strong electric field, or an RF (radio frequency) electromagnetic field.

For a plasma etcher, an RF signal is applied to an electrostatic chuck to generate plasma. In this case, the plasma density distribution is not uniform due to the limited area of the electrostatic chuck, and thus a focus ring or an edge ring is located at the edge of the electrostatic chuck. Such the focus ring or edge ring can only control an initial plasma state in the edge region, and the initial controlled state changes by consumption of the focus ring or edge ring by plasma during plasma process.

That is, it is possible to control the initial edge plasma by the focus ring or the edge ring, but plasma control in a center of the substrate is impossible. Therefore, it is impossible to control a high density plasma and thereby a high etching rate in the central region by high frequency harmonics.

### SUMMARY

Embodiments of the inventive concept provide a substrate treating apparatus for controlling harmonics generated during a plasma treatment.

The technical objectives of the inventive concept are not limited to the above-mentioned ones, and the other unmentioned technical objects will become apparent to those skilled in the art from the following description.

An embodiment of the inventive concept provides a substrate treating apparatus.

The apparatus comprises: a processing chamber having a processing space therein; a support unit for supporting a substrate in the processing space; a gas supply unit for supplying processing gas into the processing space; and a RF power source for supplying a RF signal to the processing gas to generate plasma, wherein the support unit comprises: an edge ring surrounding the substrate; a coupling ring disposed under the edge ring and including an electrode therein; and a cable having one end connected to the electrode and the opposite end connected to a ground.

In an embodiment, a length of the cable is variable.

In an embodiment, the cable is provided in a length having a low impedance to remove a harmonic component of the plasma generated in in the processing chamber.

In an embodiment, the cable is provided in a length to have an impedance of about 50Ω to 1000Ω.

In an embodiment, the substrate treating apparatus may further comprise a circuit unit connected between the cable and the ground.

In an embodiment, the circuit unit comprises a resistor connected in series with the cable.

In an embodiment, the circuit unit comprises a filter circuit passing only a specific wavelength.

In an embodiment, the filter circuit comprises at least one of a band pass filter, a low pass filter, and a high pass filter.

In an embodiment, the filter circuit is any one of a band pass filter, a high pass filter, and a combination of the band pass filter and the high pass filter.

A substrate treating apparatus according to another aspect of the inventive concept is provided.

The apparatus comprises: a processing chamber having an inner processing space therein; a support unit for supporting a substrate in the processing space; a gas supply unit for supplying processing gas into the processing space; and a RF power source for supplying a RF signal to the processing gas to generate plasma, wherein the support unit comprises: an edge ring surrounding the substrate; a coupling ring disposed under the edge ring and including an electrode therein; and a cable having one end connected to the electrode and the opposite end connected to a ground, the cable having a fixed length, and wherein the substrate treating apparatus further comprises a circuit unit connecting the ground and the cable with each other.

In an embodiment, an impedance of the circuit unit is adjusted to be lower than an impedance of a harmonic component desiring to be removed from a harmonic component generated in the processing chamber.

In an embodiment, the impedance of the circuit unit is adjusted by comparing the harmonic component and a sum of an impedance of the circuit unit and an impedance of the cable.

In an embodiment, the sum of the impedance of the circuit unit and the impedance of the cable impedance of the cable is adjusted to a range of about 50Ω to 1000Ω.

In an embodiment, the circuit unit comprises a variable impedance device, and an impedance of the circuit unit is adjusted by adjusting the variable impedance device.

In an embodiment, the variable impedance device comprises at least one of a variable capacitor, a variable inductor, and a variable resistor.

A substrate treating method using a substrate treating apparatus of an embodiment of the inventive concept to generate a plasma inside a processing chamber is provided.

The method adjusts the length of the cable to remove a harmonic component generated within the processing chamber.

In an embodiment, the length of the cable is adjusted such that the cable has an impedance in the range of about 50Ω to 1000Ω.

The method removes a harmonic component within the processing chamber by adjusting an impedance of a variable device of the circuit unit.

In an embodiment, the impedance of the variable device is adjusted such that a total impedance of the circuit unit and the cable is about 50Ω to 1000Ω.

According to the inventive concept, harmonics generated in the plasma treatment may be controlled through length adjustment of the cable.

According to an embodiment of the inventive concept, harmonics generated in the plasma treatment may be controlled through adjustment of the circuit unit connected to the cable.

According to the inventive concept, the etching rate of the central region of the substrate may be controlled.

The effects of the inventive concept are not limited to the above-described effects, and effects not mentioned will be clearly understood by those skilled in the art from the present specification and the accompanying drawings.

### BRIEF DESCRIPTION OF THE FIGURES

The above and other objects and features will become apparent from the following description with reference to the following figures, wherein like reference numerals refer to like parts throughout the various figures unless otherwise specified, and wherein:

FIG. 1a to FIG. 1b are exemplary views illustrating a substrate treating apparatus according to an embodiment of the inventive concept;

FIG. 2 is an enlarged block diagram of the substrate treating apparatus according to an embodiment of the inventive concept;

FIG. 3 is a view illustrating calculating an impedance of a cable;

FIG. 4 is a view illustrating that an etching rate ER of a central region is adjusted according to a change in f3 MHz component impedance |Z| of a cable.

FIG. 5 is a view illustrating a substrate treating apparatus according to an embodiment of the inventive concept;

FIG. 6a to FIG. 6b are views illustrating a configuration of a circuit unit according to an embodiment of the inventive concept.

### DETAILED DESCRIPTION

The inventive concept may be variously modified and may have various forms, and specific embodiments thereof will be illustrated in the drawings and described in detail. However, the embodiments according to the concept of the inventive concept are not intended to limit the specific disclosed forms, and it should be understood that the present inventive concept includes all transforms, equivalents, and replacements included in the spirit and technical scope of the inventive concept. In a description of the inventive concept, a detailed description of related known technologies may be omitted when it may make the essence of the inventive concept unclear.

The terminology used herein is for the purpose of describing particular embodiments only and is not intended to be limiting of the inventive concept. As used herein, the singular forms “a”, “an” and “the” are intended to include the plural forms as well, unless the context clearly indicates otherwise. It will be further understood that the terms “comprise(s)”, “comprising,”, “include(s)”, “including”, “have”, “having”, etc., when used in this specification, specify the presence of stated features, integers, steps, operations, elements, and/or components, but do not preclude the presence or addition of one or more other features, integers, steps, operations, elements, components, and/or groups thereof. As used herein, the term “and/or” includes any and all combinations of one or more of the associated listed items. Also, the term “exemplary” is intended to refer to an example or illustration.

It will be understood that, although the terms “first”, “second”, “third”, etc., may be used herein to describe various elements, components, regions, layers and/or sections, these elements, components, regions, layers and/or sections should not be limited by these terms. These terms are only used to distinguish one element, component, region, layer or section from another region, layer or section. Thus, a first element, component, region, layer or section discussed below could be termed a second element, component, region, layer or section without departing from the teachings of the inventive concept. As used herein, ‘˜unit’ and ‘˜module’ may refer to means for processing at least one function or operation, and may refer to, for example, software, or a hardware component such as FPGA or ASIC. However, ‘˜unit’ and ‘˜module’ may not be limited to the software or the hardware. ‘˜unit’ and ‘˜module’ may be configured to reside on an addressable storage medium and may be configured to reproduce one or more processors. In an example, ‘˜unit’ and ‘˜module’ may refer to components such as software components, object-oriented software components, class components and task components, processes, functions, properties, procedures, subroutines, segments of a program code, drivers, firmware, microcode, a circuit, data, database, data structures, tables, arrays, and variables. A function provided by a component, ‘˜unit’ or ‘˜module’ may be performed in a separate manner using a plurality of components, a plurality of ‘˜units’ or a plurality of ‘˜modules’. A component, ‘˜unit’ or ‘˜module’ may be integrated with an additional component.

Hereinafter, embodiments of the inventive concept will be described in detail with reference to the accompanying drawings.

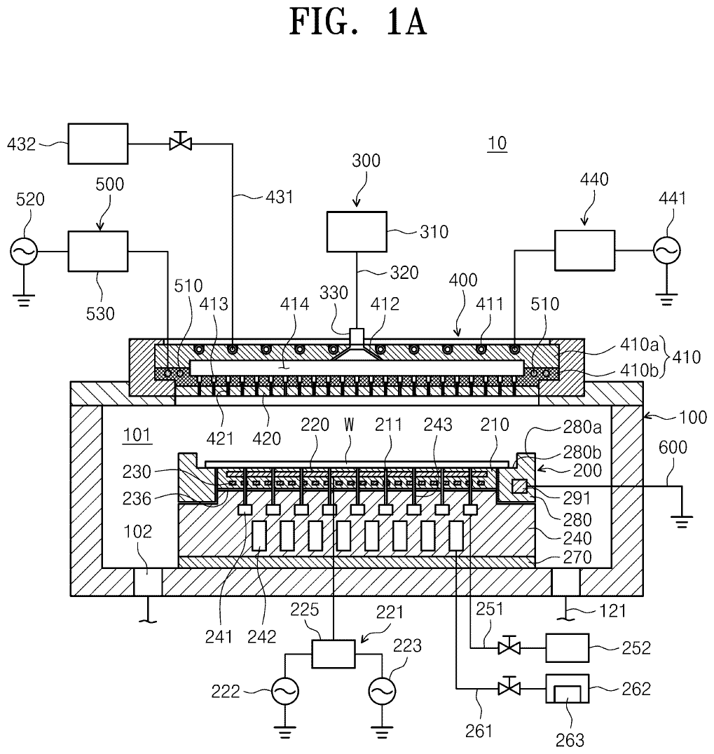

FIG. 1a to FIG. 1b illustrate a substrate treating apparatus 10 according to an embodiment of the inventive concept.

Referring to FIG. 1a, the substrate treating apparatus 10 treats the substrate W using plasma. For example, the substrate treating apparatus 10 may perform an etching process on the substrate W. The substrate treating apparatus 10 comprises a chamber 100, a substrate support unit 200, a gas supply unit 300, a plasma generating unit 400, and a heating unit 500.

The chamber 100 has an inner space 101 defined therein. The inner space 101 act as a space in which a plasma treating is carried out on the substrate W. The plasma treating on the substrate W includes an etching process. An exhaust hole 102 is formed in a bottom of the chamber 100. The exhaust hole 102 is connected to an exhaust line 121. Reaction by-products generated during the process and gas staying in the chamber 100 may be discharged to an outside through the exhaust line 121. The inner space 101 of the chamber 100 is decompressed to a predetermined pressure via an exhaust process.

The substrate support unit 200 is located inside the chamber 100. The substrate support unit 200 supports the substrate W. The substrate support unit 200 includes an electrostatic chuck for sucking and fixing the substrate W using electrostatic force. The substrate support unit 200 may include a dielectric plate 210, a lower electrode 220, a heater 230, a support plate 240, and an insulating plate 270.

The dielectric plate 210 is located on an upper end of the substrate support unit 200. The dielectric plate 210 act as a circular shaped dielectric plate. The substrate W may be disposed on a top face of the dielectric plate 210. The top face of the dielectric plate 210 has a diameter smaller than the substrate W. Therefore, the edge region of the substrate W is located out of the dielectric plate 210. A first supply channel 211 is formed in the dielectric plate 210. The first supply channel 211 extends from the top face of the dielectric plate 210 to a bottom face thereof. A plurality of first supply channels 211 are spaced apart from each other, and serve as a passage through which a heat transfer medium is supplied to a bottom face of the substrate W. A separate electrode for sucking the substrate W to the dielectric plate 210 may be embedded in the dielectric plate 210. A direct current may be applied to the electrode. An electrostatic force acts between the electrode and the substrate under the applied current, such that the substrate W may be sucked to the dielectric plate 210 via the electrostatic force.

The lower electrode 220 is connected to a lower power source unit 221. The lower power source unit 221 applies power to the lower electrode 220. The lower power source unit 221 includes lower RF power sources 222 and 223 and a lower impedance matching unit 225. As shown in FIG. 1, a plurality of lower RF power sources 222 and 223 may be provided, or alternatively only one lower RF power source 222 and 223 may be provided. The lower RF power sources 222 and 223 may control a plasma density. The lower RF power sources 222 and 223 mainly control ion bombardment energy. The plurality of lower RF power sources 222 and 223 may generate frequency power of 2 MHz and 13.56 Hz, respectively. The lower impedance matching unit 225 is electrically connected to the lower RF power sources 222 and 223, and matches frequency power of different magnitudes with each other and applies the matched frequency powers to the lower electrode 220.

The heater 230 is electrically connected to an external power source (not shown). The heater 230 generates heat by resisting against a current applied from the external power source. The generated heat is transferred to the substrate W via the dielectric plate 210. The substrate W is maintained at a predetermined temperature using heat generated by the heater 230. The heater 230 includes a coil having a spiral shape. The heater 230 may be embedded in the dielectric plate 210 and be spaced apart from each other by a uniform spacing.

The support plate 240 is located under the dielectric plate 210. A bottom face of the dielectric plate 210 and a top face of the support plate 240 may be bonded to each other via an adhesive 236. The support plate 240 may be made of an aluminum material. The top face of the support plate 240 may be stepped so that a central region thereof is higher than an edge region thereof. The central region of the top face of the support plate 240 has an area corresponding to an area of the bottom face of the dielectric plate 210, and is adhered to the bottom face of the dielectric plate 210. A first circulation channel 241, a second circulation channel 242, and a second supply channel 243 are formed in the support plate 240.

The first circulation channel 241 acts as a passage through which the heat transfer medium circulates. The first circulation channel 241 may be formed in a spiral shape and inside the support plate 240. Alternatively, the first circulation channel 241 may be constructed so that ring-shaped channels having different radii may be arranged around the same center. The first circulation channels 241 may communicate with each other. The first circulation channels 241 may be located at the same vertical level.

The second circulation channel 242 serves as a passage through which a cooling fluid circulates. The second circulation channel 242 may be formed in a spiral shape and inside the support plate 240. Alternatively, the second circulation channel 242 may be constructed such that ring-shaped channels having different radii may be arranged around the same center. The second circulation channels 242 may communicate with each other. The second circulation channel 242 may have a greater cross-sectional area than that of the first circulation channel 241. The second circulation channels 242 may be located at the same vertical level. The second circulation channel 242 may be located below the first circulation channel 241.

The second supply channel 243 extends upward from the first circulation channel 241 and extends to a top face of the support plate 240. A plurality of second supply channels 243 are provided such that the number thereof corresponds to the number of the first supply channels 211. The second supply channel 243 connects the first circulation channel 241 and the first supply channel 211 to each other.

The first circulation channel 241 is connected to a heat transfer medium storage unit 252 via a heat transfer medium supply line 251. The heat transfer medium is stored in the heat transfer medium storage unit 252. The heat transfer medium includes an inert gas. According to an embodiment, the heat transfer medium includes helium He gas. The helium gas is supplied to the first circulation channel 241 through the heat transfer medium supply line 251, and sequentially flows through the second supply channel 243 and the first supply channel 211 and then is supplied to the bottom face of the substrate W. The helium gas acts as a medium via which heat transferred from the plasma to the substrate W is transferred to the substrate support unit 200. Ion particles contained in the plasma are attracted using an electric force generated in the substrate support unit 200 and travel to the substrate support unit 200, and collide with the substrate W during the travel to perform an etching process. As the ionic particles collide with the substrate W, the heat is generated in the substrate W. The heat generated from the substrate W is transferred to the substrate support unit 200 via the helium gas supplied to a space between the bottom face of the substrate W and the top face of the dielectric plate 210. Thus, the substrate W may be maintained at a set temperature.

The second circulation channel 242 is connected to a cooling fluid storage unit 262 via a cooling fluid supply line 261. The cooling fluid is stored in the cooling fluid storage unit 262. A cooler 263 may be provided within the cooling fluid storage unit 262. The cooler 263 cools the cooling fluid to a predetermined temperature. Alternatively, the cooler 263 may be installed on the cooling fluid supply line 261. The cooling fluid supplied to the second circulation channel 242 through the cooling fluid supply line 261 circulates along the second circulation channel 242 and cools the support plate 240. The cooling of the support plate 240 cools the dielectric plate 210 and the substrate W together to maintain the substrate W at a predetermined temperature.

The insulating plate 270 is provided under the support plate 240. In some embodiments, the insulating plate 270 may be electrically non-conductive. The insulating plate 270 has size corresponding to that of the support plate 240. The insulating plate 270 is located between the support plate 240 and a bottom face of the chamber 100. The insulating plate 270 is made of an insulating material, and electrically insulates the support plate 240 and the chamber 100 from each other.

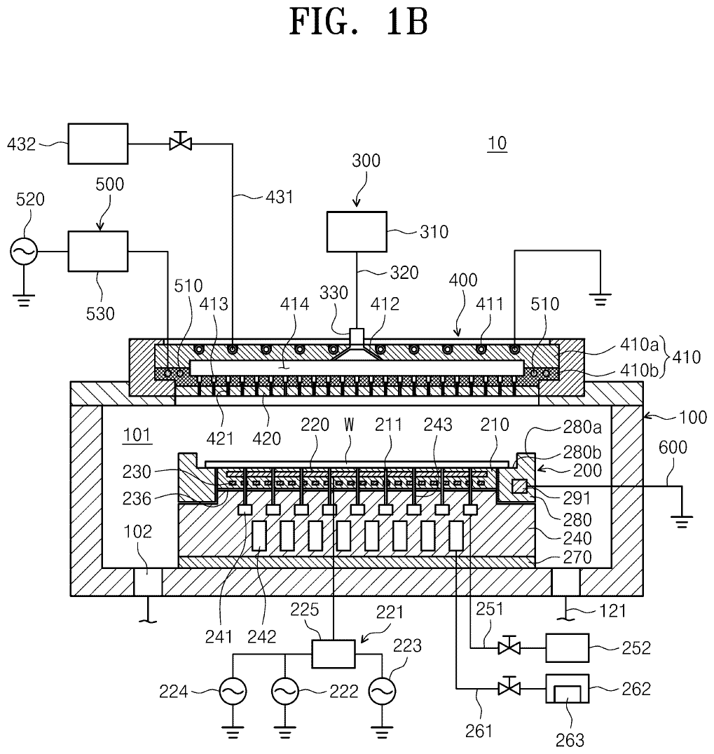

An edge ring 280 is disposed in an edge region of the substrate support unit 200. The edge ring 280 has a ring shape and extends along a periphery of the dielectric plate 210. A top face of the edge ring 280 may be stepped so that an outer portion 280a thereof may be higher than an inner portion 280b thereof. The inner portion 280b of the top face of the edge ring 280 is positioned at the same vertical level as that of the top face of the dielectric plate 210. The inner portion 280b of the top face of the edge ring 280 supports thee edge region of the substrate W positioned out of the dielectric plate 210. The outer portion 280a of the edge ring 280 is provided to surround the edge region of the substrate W. The edge ring 280 expands the electric field forming region so that the substrate W is located at a center of a plasma generated region. Thus, the plasma is uniformly generated over an entire area of the substrate W, so that the regions the substrate W may be uniformly etched. A coupling ring (not shown) may be disposed below the edge ring 280. A cable 600 may be connected to the coupling ring (not shown in FIG. 1) via one end thereof. The opposite end of the cable 600 may be connected to a ground. In an embodiment, the cable 600 may be a variable cable with a variable length. According to an embodiment, the length of the cable 600 may be fixed, and in this case a circuit unit (not shown in FIG. 1) capable of controlling an impedance of the cable may be further provided. In the exemplary embodiments according to an inventive concept, the impedance of the cable which is connected to the coupling ring can be controlled for example by controlling the length there of and/or controlling the circuit unit to remove harmonics of plasma generated by the RF power source. A detailed description thereof will be described later with reference to FIG. 2.

The gas supply unit 300 supplies a processing gas to the chamber 100. The gas supply unit 300 includes a gas storage unit 310, a gas supply line 320, and a gas inlet port 330. The gas supply line 320 connects the gas storage unit 310 and the gas inlet port 330 to each other, and supplies the processing gas stored in the gas storage unit 310 to the gas inlet port 330. The gas inlet port 330 is connected to gas supply holes 412 formed in an upper electrode 410.

The plasma generating unit 400 excites the processing gas remaining inside the chamber 100. The plasma generating unit 400 includes the upper electrode 410, a distribution plate 420, and an upper power source unit 440.

The upper electrode 410 has a shape of a disk and is located above the substrate support unit 200. The upper electrode 410 includes an upper plate 410a and a lower plate 410b. The upper plate 410a has a disk shape. The upper plate 410a is electrically connected to an upper RF power source 441. The upper plate 410a excites the processing gas by applying a first RF power generated by the upper RF power source 441 to the processing gas staying in the chamber 100. The processing gas is excited and converted into a plasma state. A bottom face of the upper plate 410a is stepped so that a central region thereof is higher than an edge region thereof. The gas supply holes 412 are formed in the central region of the upper plate 410a. The gas supply holes 412 are connected to the gas inlet port 330 and supply processing gas to a buffer space 414. A cooling channel 411 may be formed inside the upper plate 410a. The cooling channel 411 may be formed in a spiral shape. Alternatively, the cooling channel 411 may be constructed so that ring-shaped channels having different radii may be arranged around the same center. The cooling channel 411 is connected to a cooling fluid storage unit 432 via a cooling fluid supply line 431. The cooling fluid storage unit 432 stores a cooling fluid therein. The cooling fluid stored in the cooling fluid storage unit 432 is supplied to the cooling channel 411 via the cooling fluid supply line 431. The cooling fluid circulates through the cooling channel 411 and cools the upper plate 410a.

The lower plate 410b is positioned below the upper plate 410a. The lower plate 410b has a size corresponding to that of the upper plate 410a, and is positioned to face toward the upper plate 410a. Atop face of the lower plate 410b is stepped so that a central region thereof is lower than an edge region thereon. The top face of the lower plate 410b and a bottom face of the upper plate 410a are coupled to each other to form the buffer space 414. The buffer space 414 acts as a space where the gas supplied through the gas supply holes 412 temporarily stays before being supplied into the chamber 100. Gas supply holes 413 are formed in the central region of the lower plate 410b. A plurality of gas supply holes 413 are arranged and spaced apart from each other by a regular spacing. The gas supply holes 413 are connected to the buffer space 414.

The distribution plate 420 is positioned below the lower plate 410b. The distribution plate 420 has a shape of a disk. Distribution holes 421 are formed in the distribution plate 420. The distribution holes 421 extend from a top face of the distribution plate 420 to a bottom face of thereof. The number of the distribution holes 421 corresponds to the number of the gas supply holes 413, and the distribution holes 421 are respectively located in positions corresponding to positions where the gas supply holes 413 are located. The processing gas staying in the buffer space 414 is uniformly supplied into the chamber 100 via the gas supply hole 413 and the distribution holes 421.

The upper power source unit 440 applies RF power to the upper plate 410a. The upper power source unit 440 includes the upper RF power source 441 and a matching circuit 442.

The heating unit 500 heats the lower plate 410b. The heating unit 500 includes a heater 510, a second upper power source 520, and a filter 530. The heater 510 is installed inside the lower plate 410b. The heater 510 may be disposed in an edge region of the lower plate 410b. The heater 510 may include a heating coil and may be provided to surround a central region of the lower plate 410b. The second upper power source 520 is electrically connected to the heater 510. The second upper power source 520 may generate DC power. Alternatively, the second upper power source 520 may generate AC power. The second frequency power generated by the second upper power source 520 is applied to the heater 510, and the heater 510 generates heat by resisting against the applied current. The heat generated by the heater 510 heats the lower plate 410b, and the heated lower plate 410b heats the distribution plate 420 located below the lower plate 410b to a predetermined temperature. The lower plate 410b may be heated to a temperature of about 60° C. The filter 530 is electrically connected to the second upper power source 520 and the heater 510 and disposed between the second upper power source 520 and the heater 510.

FIG. 1b illustrates a substrate treating apparatus 10 according to an embodiment of the inventive concept.

Descriptions about configurations in an embodiment of FIG. 1b duplicate with those of FIG. 1a will be omitted.

According to an embodiment of FIG. 1b, the lower electrode 220 is connected to the lower power source unit 221. The lower power source unit 221 applies power to the lower electrode 220. The lower power source unit 221 may include three high frequency power sources 222, 223, and 224. The lower power source unit 221 may include a lower impedance matching unit 225.

In an embodiment, two of the three lower power sources 222, 223, and 224 may be a first frequency power source 222 and a second frequency power source 223 having a frequency of 10 MHz or less, and the other lower power source may be a third frequency power source 224 having a frequency of 10 MHz or more. The first frequency power source 222 and the second frequency power source 223 may control an ion bombardment energy, and the third frequency power source 224 may control plasma density. The upper electrode 410 may be grounded.

However, the number of power sources in the embodiments illustrated in FIG. 1a and FIG. 1b is not limited thereto, and may be only an embodiment.

FIG. 2 illustrates a substrate processing apparatus according to an embodiment of the inventive concept.

The substrate support unit 200 according to the inventive concept may include an edge ring 280 surrounding the substrate W, and a coupling ring 290 disposed below the edge ring 280. Insulators 281 and 282 may be included between the edge ring 280 and the coupling ring 290. According to an embodiment of FIG. 2, two insulators 281 and 282 are provided, but both may be combined into one insulator.

An electrode 291 may be included within the coupling ring 290. One end of a cable 600 may be connected to the electrode 291 included within the coupling ring 290. The opposite end of the cable 600 may be connected to a ground. The cable 600 may provide an impedance path to the ground to the RF signal for an incoming RF signal in the edge region of the substrate W. The RF signal may flow to the electrode 291 using capacitance between the edge ring 280 and the electrode 291. The electrode 291 may output the RF signal.

Referring to FIG. 2, the cable 600 may be provided in the form of a variable cable to be adjustable in length. Although not shown in FIG. 2, the cable 600 may further include a length adjustment means capable of adjusting the length of the cable. According to an embodiment, the cable 600 may be provided with a fixed length. By adjusting the length of the cable 600, an impedance off the cable 600 may be adjusted. By adjusting the impedance of the cable to a constant value, a target harmonic component among harmonic components generated in the process chamber can be selectively removed.

According to an embodiment, the cable 600 may be adjusted to have a length which can remove harmonics of plasma having about 100 MHz or more. This is because a plasma density concentration in the central region is greatly affected at a frequency of about 100 MHz or more.

According to the inventive concept, the electrode 291 may be inserted inside the coupling ring 290 located below the edge ring 280, and the electrode 291 and the ground may be connected to each other by the cable 600 to remove only harmonics of the plasma from the processing chamber to the ground. According to the inventive concept, plasma uniformity may be controlled by removing the harmonics by setting the length of the cable 600 when connected to the electrode 291 included inside the coupling ring 290 below. The setting of the length of the cable 600 may be done in advance by calculation before connected to the electrode 291. Alternatively the length of the cable 600 may be changed during processing using a variable cable the length of which can be varied.

In an embodiment, if the impedance of the cable connected to the ground is lower than that of the harmonics, the harmonics in the processing chamber may be removed to the ground via the cable. Removing the harmonics may allow for suppressing high plasma density and thus high etching rate in the central region of the substrate W and thus. According to an embodiment, the impedance of the cable (cable impedance) may be adjusted to a value between about 50 and 1000Ω for all harmonics. The length of the cable may be adjusted as to remove all harmonics. According to an embodiment, the length of the cable may be adjusted so that the cable 600 has an impedance of about 200Ω or less. According to an embodiment, the length of the cable may be adjusted so that the cable 600 has an impedance in the range of about 50 and 1000Ω.

That is, the length of the cable according to an embodiment of the inventive concept may be provided as a fixed length through calculation in advance and alternatively the cable may be provided as a variable-length cable so that the length of the cable may vary in real time based on applied frequencies of the RF signal.

Hereinafter, adjusting the impedance of the cable by adjusting the length of the cable will be described in more detail.

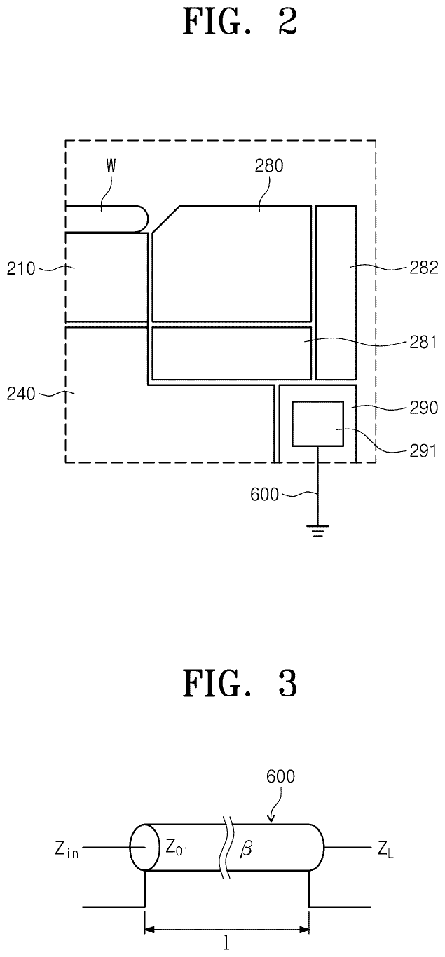

FIG. 3 illustrates calculating the impedance of the cable.

In the case of a coaxial cable, the impedance of the cable Zᵢₙ changes according to the length of the cable and frequency. The impedance of the cable Zᵢₙ can be expressed by the following equation: Zᵢₙ=Z₀(Z_{L}+jZ₀ tan(βl))/(Z₀+jZ_{L} tan(βl)).

In the above equation, is the impedance of the cable, Z_{L} is an impedance of the load connected to the cable, β is a propagation constant, and Z₀ is a characteristic impedance of the cable. According to an embodiment, the characteristic impedance of the cable Z₀ may be 50Ω. In this case, the propagation constant has a relationship of β=2πf/cη (wherein f is a frequency, c is a propagation speed in a vacuum, and η is a velocity factor (VF) determined by cable characteristics) and varies depending on the frequency f.

As shown in FIG. 2, when the opposite end of the cable is directly connected to the ground, the load impedance Z_{L}=0, thus the impedance of the cable may be expressed as follows: Zᵢₙ=j50 tan(βl).

That is, the impedance of the cable may be adjusted according to the applied frequency and the length of the cable.

According to an embodiment, when the frequency of the RF power source is f1 MHz, the frequency of the harmonics includes f2(=f1×2) MHz, f3(f1×3) MHz, f4(f1×4) MHz, . . . , and fn(f1×n) MHz which are integer times of f1 MHz. Here, f1 may be 10 MHz or more and the frequency of the harmonics may be 100 MHz or more. In this case, the cable impedance may be calculated based on the length of the cable and the velocity factor η.

TABLE 1

| f (MHz) | \|Z\| (Ω) |
|---|---|
| f₁ | Z₁ |
| f₂ | Z₂(«Z₁) |
| f₃ | Z₃(<Z₁) |
| f₄ | Z₄(«Z₁) |

According to Table 1, f2 MHz and f4 MHz harmonics causing plasma asymmetry may be removed through the ground while maintaining a high impedance in order to suppress loss through a cable of f1 MHz applied by RF power. In Table 1, f1, f2, f3 and f4 may be 60 MHz, 120 MHz, 180 MHz and 240 MHz, respectively, and Z1, Z2, Z3 and Z4 may be respectively 2124 Ω, 2Ω, 707Ω and 5Ω, respectively, the length of the cable may be 2.9 m and η may be 0.77.

Such a cable length may be used when plasma asymmetry is severe due to f2 MHz and f4 MHz harmonics. When plasma asymmetry in the central area is severe due to f3 MHz harmonics, cable length may be adjusted such that the cable has a low impedance for f3 MHz.

That is, according to the inventive concept, since the plasma density in the central area of the substrate by the harmonics is controlled according to the length of the cable, the etching rate in the central area of the substrate may be controlled by replacing the cable or using a variable length cable.

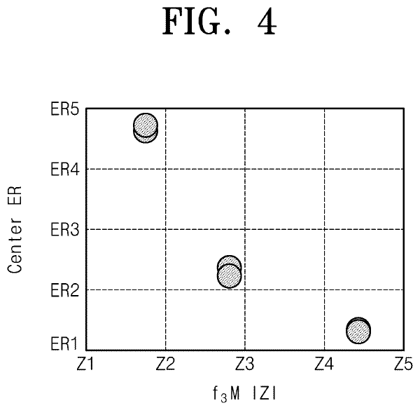

FIG. 4 illustrates that an etching rate ER in the central area of the substrate is adjusted according to a change in an impedance |Z| of the cable for f3 MHz harmonics.

Referring to FIG. 4, it shows that the etching rate in the central area of the substrate can be changed by adjusting the impedance |Z| of the cable for f3 MHz.

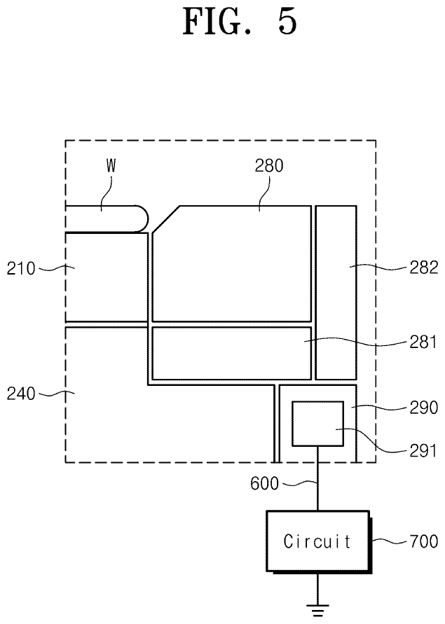

FIG. 5 illustrates a substrate processing apparatus according to an embodiment of the inventive concept.

According to an embodiment of FIG. 5, the cable 600 may further include a circuit unit 700. The circuit unit 700 may be connected between the cable 600 and the ground. According to an embodiment, when the cable 600 connected to the electrode 291 is a variable cable capable of length adjustment, since the impedance of the cable can be adjusted by adjusting the length of the variable cable, the circuit unit 700 connected to the variable cable may be configured to have secondary functions such as suppressing heat generation or preventing loss of the main RF frequency, instead of having a primary function of controlling an impedance of the cable. However, the circuit unit 700 may have function to control the impedance of the cable.

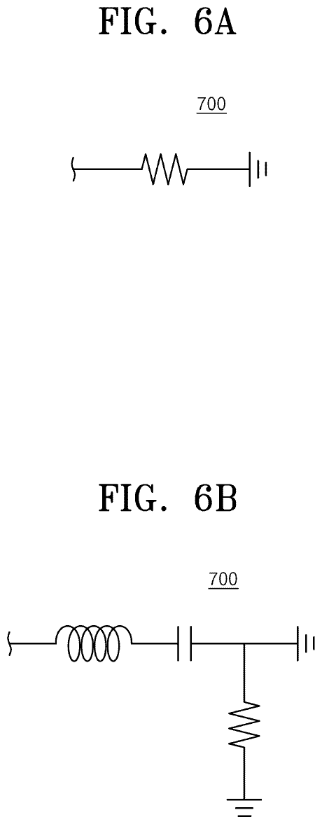

FIG. 6a to FIG. 6b illustrate a configuration of the circuit unit 700 according to an embodiment of the inventive concept.

Referring to FIG. 6a, the circuit unit 700 includes a resistor R. When the circuit unit 700 includes the resistor R, heat generation due to a high current can be suppressed.

Referring to FIG. 6b, the circuit unit 700 includes an inductor, a capacitor and a resistor. The inductor and the capacitor in combination act as a filter circuit that prevents a main RF frequency from being transmitted to the ground regardless of a cable length. According to an embodiment, the filter circuit may be a band pass filter BPF or a low pass filter LPF. According to an embodiment, the filter circuit may be a high pass filter HPF. According to an embodiment, the filter circuit may include combinations of a high pass filter HPF, a band pass filter BPF, and/or a low pass filter LPF.

However, the configuration illustrated in FIG. 6a to FIG. 6b is only an embodiment, and the circuit unit 700 according to the inventive concept may be provided to have the above-described function through various combinations of an inductor, a capacitor, and a resistor. The configuration shown in FIG. 6a to FIG. 6b may be example configuration of the circuit unit connected to a variable cable whose length may vary according to an embodiment.

However, according to an embodiment of the inventive concept, the cable 600 may be provided as a cable having a fixed length. In the case of the circuit unit connected to the cable with a fixed length, since the impedance of the fixed cable varies only by frequency, the circuit unit may be connected to the cable with a fixed length may control the impedance of the cable when a desired impedance is not achieved via frequency control. That is, when there is a limitation in the length configuration of the cable, the impedance may be compensated through the circuit unit.

At this time, the circuit unit is provided to include at least one of a variable resistor, a variable capacitor, a variable inductor or combinations thereof, and thus the impedance may be adjusted through adjustment of the variable devices.

Even in the case the circuit unit is connected to the cable with a fixed length, it is also possible to include a resistor and/or filter circuit functioning as a secondary function, such as the circuit unit connected to the variable cable. However, in the case of the circuit unit connected to the cable with a fixed length, it can include variable elements capable of adjusting impedance in addition to circuits that perform secondary functions. That is, in the case of such an embodiment, the impedance control can be carried out by adjusting the variable elements included in the circuit, without replacing the cable.

That is, in this case, the impedance of the circuit unit may be controlled by comparing a total impedance (i.e., a sum) of an impedance adjusted through the circuit unit and an impedance of the cable having a fixed length, and the harmonics of plasma generated in the process chamber. According to an embodiment, the variable elements included in the circuit unit can be controlled such that the total impedance of an impedance adjusted through the circuit unit and an impedance of the cable having a fixed length is in the range of about 50 to 1000Ω.

In addition, according to an embodiment of the inventive concept, if an impedance TTTM between facilities is desired by compensating for a deviation between cables, the impedance may be controlled via the circuit unit to achieve the cable impedance TTTM.

That is, the circuit unit 700 connected to the cable 600 according to the inventive concept may include an overcurrent prevention circuit, a main RF frequency blocking filter, a variable impedance control circuit, a harmonic blocking filter, a harmonics transmission filter, etc, and/or combinations thereof.

That is, according to an embodiment of the inventive concept, plasma asymmetry may be suppressed by selecting a cable length such that the cable has a low impedance with respect to the harmonics to be removed and connecting the cable between the electrode and the ground to remove the target harmonics to the ground. Alternatively, the target harmonics may be removed to the ground by varying the cable length in real time.

According to an embodiment of the inventive concept, when the length of the cable may not be changed, plasma asymmetry may be suppressed by additionally controlling impedance to be low via the circuit unit to remove the target harmonics to the ground.

In addition, the circuit unit 700 according to the inventive concept may further include an impedance control circuit for controlling a sheath voltage in an edge area. Accordingly, the sheath of the edge region may be controlled in real time and the initial setting of the plasma density in the central area may be performed. Accordingly, sheath and ion tilting of the edge area may be controlled.

In addition, the circuit unit 700 according to the inventive concept may further include an impedance control circuit for sheath voltage control in the edge area and an impedance control circuit for harmonics control, thereby simultaneously controlling sheath and ion tilting in the edge area and controlling harmonics and plasma density in the central area.

According to an embodiment of the inventive concept, when the etching rate in the central area is low, according to the chamber, plasma asymmetry may be compensated and controlled by amplifying or adjusting harmonics in addition to removing harmonics. Through this, the etching rate in the overall areas may be uniformly adjusted.

The effects of the inventive concept are not limited to the above-mentioned effects, and the unmentioned effects can be clearly understood by those skilled in the art to which the inventive concept pertains from the specification and the accompanying drawings.

Although the embodiment of the inventive concept has been illustrated and described until now, the inventive concept is not limited to the above-described specific embodiment, and it is noted that an ordinary person in the art, to which the inventive concept pertains, may be variously carry out the inventive concept without departing from the essence of the inventive concept claimed in the claims and the modifications should not be construed separately from the technical spirit or prospect of the inventive concept.

What is claimed is:

1. A substrate treating method comprising:
removing a harmonic component within a processing chamber by adjusting an impedance of a variable device of a circuit unit.

2. The substrate treating method of claim 1,
wherein the impedance of the variable device is adjusted such that a total impedance of the circuit unit and the cable is about 50Ω to 1000Ω.
